(19) United States
(12) Patent Application Publication
(10) Pub. No.: US 2009/0257467 A1
(43) Pub. Date: Oct. 15, 2009

(54) Group III Nitride Semiconductor Device and Method for Manufacturing Group III Nitride Semiconductor Device

(75) Inventors: Koichi Naniwae, Tokyo (JP); Ichiro Masumoto, Tokyo (JP)

Correspondence Address: FOLEY AND LARDNER LLP;SUITE 500, 3000 K STREET NW, WASHINGTON, DC, 20007, US

(73) Assignee: NEC Corporation

(21) Appl. No.: 12/084,937

(22) PCT Filed: Dec. 5, 2006
(86) PCT No.: PCT/JP2006/324233

§ 371 Date: May 14, 2008

(30) Foreign Application Priority Data
Dec. 8, 2005 (JP) 2005-354756

(51) Int. Cl. H01S 5/20; H01L 21/00

(52) U.S. Cl. 372/45.011; 438/46; 257/E21.002

(57) ABSTRACT

A laser diode 300 includes a p-type GaN guide layer 107, a current confinement layer 314 provided on the p-type GaN guide layer 107 and having an opening 314A formed therein, and a p-type cladding layer 108 provided on the current confinement layer 314 and plugging the opening 314A formed in the current confinement layer 314. An interface between the p-type cladding layer 108 and the p-type GaN guide layer 107 is located in a bottom of the opening 314A. The current confinement layer 314 is a layer of a group III nitride semiconductor, and a width dimension of the opening 314A is minimized in the upper side of the opening 314A.

### TECHNICAL FIELD

The present invention relates to a group III nitride semiconductor device and a method for manufacturing of a group III nitride semiconductor device.

### RELATED ART

Since group III nitride semiconductor materials have sufficiently wider forbidden gap and the interband transition thereof is by a direct transition, applications to short-wave light emitting devices are actively examined. In particular, as a result of rapid improvement in performances of light emitting diodes (LED) of wavelength range from ultraviolet to blue and green employing such group III nitride semiconductor from the middle of 1990's, the scope of applications of the LED employing the above-described materials is dramatically extended, and therefore considerably larger market thereof is formed. Such materials are also critical for next generation of light source for high-density optical disk, and thus researches and developments of laser diodes (LD) of emission wavelength of 405 nm are actively conducted, and practical applications of several devices are launched. Further, group III nitride semiconductors are expected to be applied to high performance devices, which considerably exceeds conventional devices employing silicon (Si) or gallium arsenide (GaAs) in terms of achieving high-temperature operation, fast switching operation, high power operation and the like, since the dielectric breakdown field thereof is expected to be larger in addition to wider forbidden gap, the saturated electron drift velocity thereof is larger and a utilization of two-dimensional carrier gas is possible by utilizing a hetero junction, and the like, and thus vigorous investigations are conducted.

In order to manufacture devices with a new function and a high performance by employing such group III nitride semiconductor, which make a significantly larger impact on the industry as described above, a technology for precisely depositing high-quality multiple-layered thin films with less defect and additionally a technology for precisely and finely processing such multiple-layered thin films to manufacture a predetermined structure are extremely critical. Descriptions will be made on such aspect, in reference to the LD.

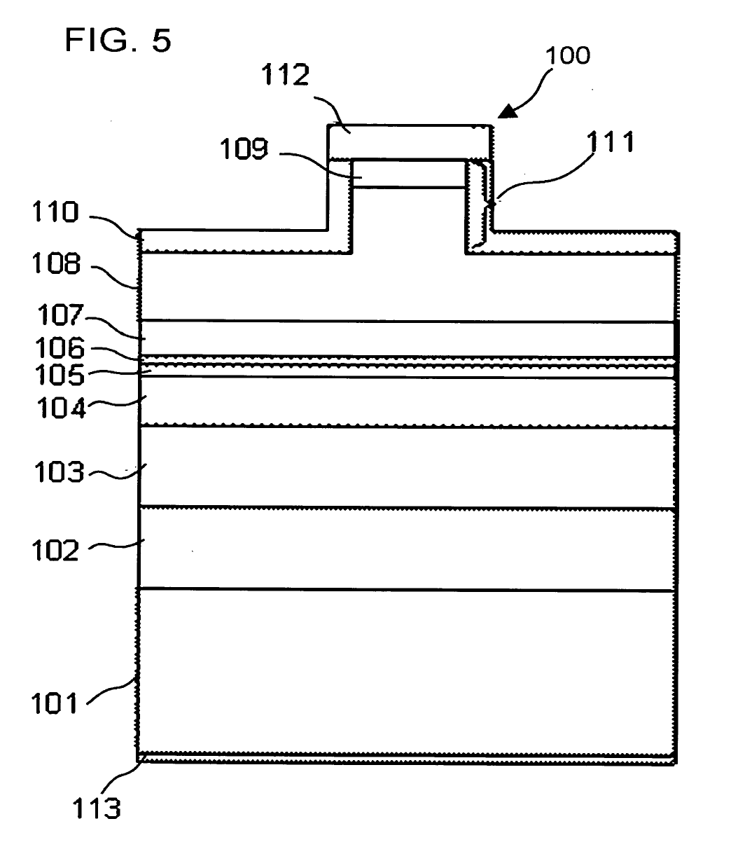

A structure shown in FIG. 5 conventionally pre-dominates the LD structures employing group III nitride semiconductors.

A semiconductor device 100 shown in FIG. 5 is obtained by depositing, on an n-type gallium nitride (GaN) substrate 101, a GaN layer 102, an n-type cladding layer 103 composed of aluminum gallium nitride (AlGaN) layer, an n-type optical confinement layer 104, a multiple-quantum well layer 105, a cap layer 106, a p-type GaN guide layer 107, a p-type cladding layer 108 composed of AlGaN layer and a p-type contact layer 109 composed of GaN layer. The p-type cladding layer 108 has a ridge 111, and a side of such ridge 111 is covered with an insulating film 110. Such insulating film 110 has an opening in the upper surface of the ridge 111, a p-type contact layer 109 and a p-electrode 112 are provided in the opening.

The current confinement is created by a ridge structure, and a control in a transverse mode is achieved by suitably adjusting a ridge width and a ridge height. Such ridge structure LD constitutively exhibits a smaller parasitic capacitance, and thus is advantageous in view of high frequency property.

The ridge structure of FIG. 5 is manufactured by using both lithography and an etching. Since chemical etching with a solution is difficult for group III nitride semiconductors, halogen dry etching is employed as the etching process. Stripe width, ridge width and ridge height of the p-electrode 112 are main parameters for transverse mode characteristics of the ridge structure LD.

Since the stripe width and the ridge width depend on the lithography process, the manufactures thereof with higher accuracy can be achieved. On the other hand, the ridge height depends on the etch amount, and depends on several parameters such as plasma conditions, flow rate of an etchant gas, a substrate temperature and the like in the etching process. Thus, the manufacture of devices over large area with higher production yield is difficult. Further, a problem of damaging an active layer by a charged particle generated in the etching process is caused.

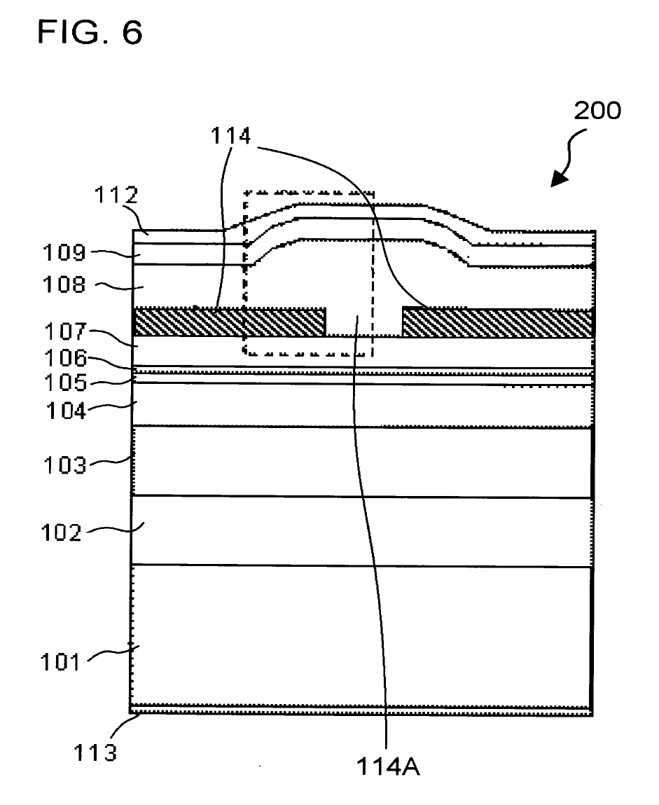

An inner stripe LD having a structure of a current confinement layer buried in an interior thereof is also proposed as a structure for achieving more efficient current confinement than the ridge structure LD. For example, a structure shown in FIG. 6 is illustrated (for example, see patent literature 1). A semiconductor device 200 shown in FIG. 6 includes, on a p-type GaN guide layer 107, a current confinement layer 114 having an opening 114A and a p-type cladding layer 108 that is formed on such current confinement layer 114 and plugs the opening 114A of the current confinement layer 114.

The current confinement layer 114 is composed of aluminum nitride (AlN), and the presence of the current confinement layer 114 provides an improved carrier injection efficiency.

Further, such current confinement layer 114 has the structure that provides a combined function of a current confinement and a transverse mode control. Since the thickness of each layer, which is influential for the transverse mode characteristics, can be controlled by a thickness of the deposited film in this structure, providing more advantageous structure as compared with the ridge structure LD, in terms of reproducibility and production yield.

Here, in producing the semiconductor device 200 shown in FIG. 6, the current confinement layer 114 serving as a non-crystalline layer is formed on the p-type GaN guide layer 107. Then, a wet etching process is conducted with an etchant solution at 80 degree C. to 120 degree C. containing phosphoric acid and sulfuric acid at a volumetric mix ratio of 1:1 to form the opening 114A.

By employing the non-crystalline layer for the current confinement layer 114 with as described above, the opening 114A can be formed by an etching process without damaging a layer underlying the current confinement layer 114.

Here, the non-crystalline layer means an amorphous layer or an amorphous layer partially containing a minor crystallization layer.

Thereafter, when the temperature of the current confinement layer 114 is increased to a temperature of equal to or higher than 900 degree C. in forming the p-type cladding layer 108 and the p-type contact layer 109. The current confinement layer 114 is grown in solid phase with the same crystal orientation as of the p-type GaN guide layer 107 to be crystallized. A large quantity of dislocations is introduced to the current confinement layer 114 in this process to cause a lattice relaxation, such that no crack is generated even if it is crystallized. Since the lattice relaxations of the p-type cladding layer 108 and the p-type contact layer 109 are also created by high-density dislocations in further growth of the p-type cladding layer 108 and the p-type contact layer 109 onto the crystallized current confinement layer 114, the growth thereof can be achieved without generating a crack.

### [Patent Literature 1]

### Japanese Patent Laid-Open No. 2003-78,215

### DISCLOSURE OF THE INVENTION

A reduction of the defects is critical for an improvement in the performances and an improvement of the production yield for the inner stripe group III nitride semiconductor device having a structure of the above-described current confinement layer composed of AlN, which is buried in an interior thereof.

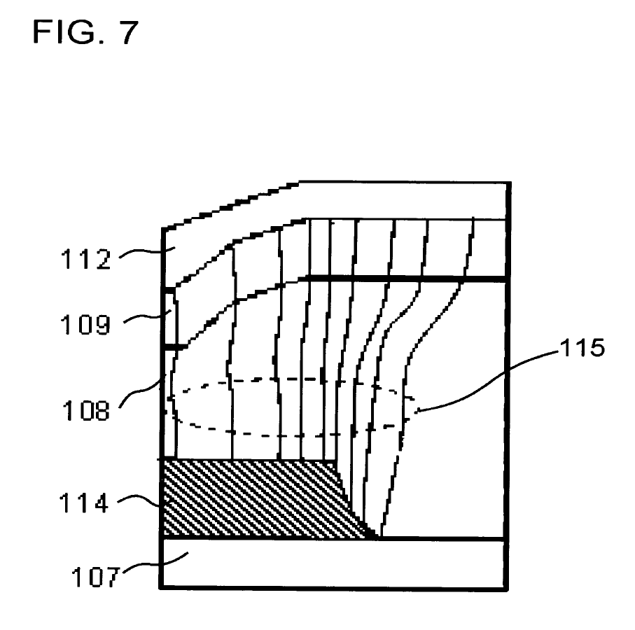

An enlarged schematic diagram of an area in vicinity of an opening 114A of a current confinement layer 114 of a conventional inner stripe type group III nitride semiconductor device 200 (section surrounded with a dotted line in FIG. 6) is shown in FIG. 7. Geometry of the opening 114A of the current confinement layer 114 is so-called forward tapered.

When the opening 114A having such geometry is formed, larger number of dislocations 115 are generated in vicinity of the opening during the growth of the p-type cladding layer 108, the p-type contact layer 109 and the like. Such dislocations 115 are propagated to the p-type cladding layer 108, the p-type contact layer 109 and the like to be a reason for reducing the device life.

Further, the larger number of dislocations generated in vicinity of the opening cause the surface strain energy to be released, so that a rate of growing crystal in vicinity of the opening is increased, leading to an increased thickness in a section of the p-type cladding layer 108 filling the opening 114A. This provides an increased operating voltage of the semiconductor device 200.

Further, such increased thickness in the section of the p-type cladding layer 108 filling the opening 114A causes uneven thickness of the p-type cladding layer 108, causing a difference in the actual optical confinement structure from the designed structure, which leads to be reasons for variations in the characteristics such as threshold current or kink level.

The reasons for generating a number of dislocations in vicinity of the opening of the conventional group III nitride semiconductor device 200 may include the following fact.

Since the geometry of the opening 114A is a forward tapered geometry in the conventional group III nitride semiconductor device 200, AlGaN, which constitutes the p-type cladding layer 108, is easily be adhered on the side wall of the current confinement layer 114 that forms the opening 114A, leading to an easy formation of crystal nuclei on the side wall that forms the opening 114A. Many dislocations are generated in the crystal grown from crystal nuclei formed on the side wall constituting the opening 114A.

It is considered that the above-described fact causes many dislocations generated in vicinity of the opening in the conventional group III nitride semiconductor device 200.

According to one aspect of the present invention, there is provided a group III nitride semiconductor device, comprising: a first layer containing a group III nitride semiconductor; a second layer, provided over the first layer and having an opening formed therein; and a third layer containing a group III nitride semiconductor, provided over the second layer and plugging the opening formed in the second layer, wherein an interface between the third layer and the first layer is located in a bottom of the opening, and wherein a width dimension of the opening in the second layer is minimized in the upper side of the opening.

Here, the upper side of the opening is a section in a side opposite to the first layer, or a section in a side opposite to the bottom of the opening.

Further, it is sufficient to satisfy “a width dimension of the opening is minimized in the upper side of the opening”, if the width dimension of the upper side of the opening is minimized in any of the cross sections perpendicular to each layer in the group III nitride semiconductor device.

Further, when the opening extends to form a stripe geometry, the width dimension of the opening may be preferably minimum in the upper side of the opening in a cross section that is perpendicular to the elongating direction of the stripe.

According to the present invention, the width dimension of the opening in the second layer is minimized in the upper side of the opening. In other words, a section of the side wall constituting the opening in the upper side of the opening is configured to be most inwardly protruded toward the inside of the opening, as compared with other sections. Therefore, source materials constituting the third layer are difficult to be adhered onto the side wall of the opening, so that crystal nuclei for the third layer are less likely to be adhered onto the side wall of the opening. This allows preventing a generation of a dislocation in vicinity of the opening.

Further, since the section of the side wall constituting the opening in the upper side of the opening is configured to be most inwardly protruded toward the inside of the opening in the present invention, the presence of the section of the opening in the upper side thereof blocks a dislocation extending from the bottom side of the opening toward the upper side. Therefore, a dislocation generated in vicinity of the opening is formed to be loop-like dislocation. This allows inhibiting a propagation of a dislocation toward the vicinity of the opening central portion in the inside of the opening or the upper portion of the third layer, preventing a decrease in the lifetime of the group III nitride semiconductor device.

Further, since a dislocation generated in vicinity of the opening is difficult to be caused, an increase of the thickness of the third layer in vicinity of the opening can be prevented.

According to one aspect of the present invention, there is provided a method for manufacturing a group III nitride semiconductor device, comprising: providing a second layer on a first layer, the first layer being a group III nitride semiconductor layer; forming an opening in the second layer; and plugging the opening of the second layer and providing a third layer, the third layer being provided on the second layer and being a group III nitride semiconductor layer, wherein the forming the opening in the second layer includes forming the opening so as to provide a minimum width dimension in the upper side of the opening.

According to the present invention, the group III nitride semiconductor device and the method for manufacturing of the group III nitride semiconductor device, which achieves preventing a decrease in the lifetime and preventing an increase of thickness of the third layer in vicinity of the opening, can be presented.

### BRIEF DESCRIPTION OF THE DRAWINGS

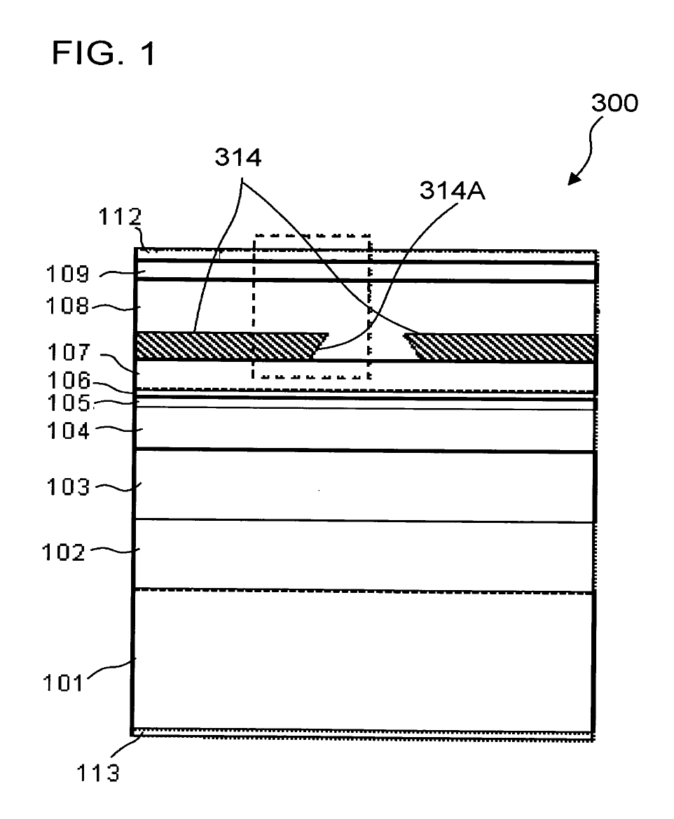

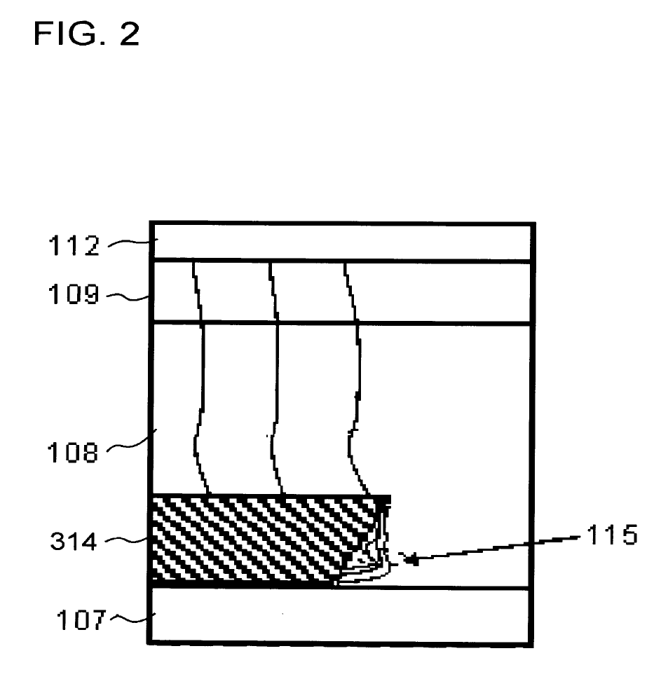

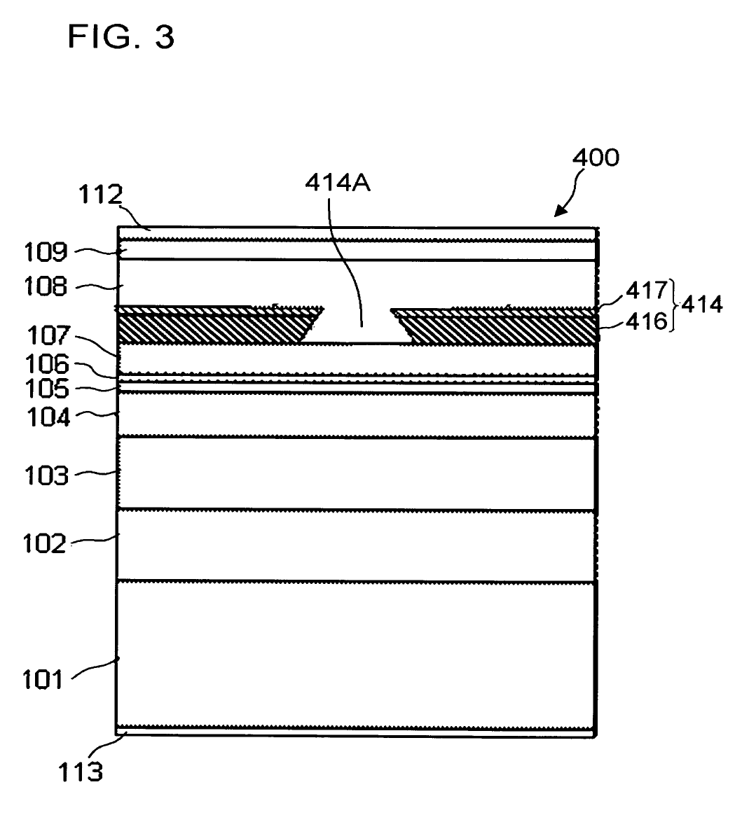

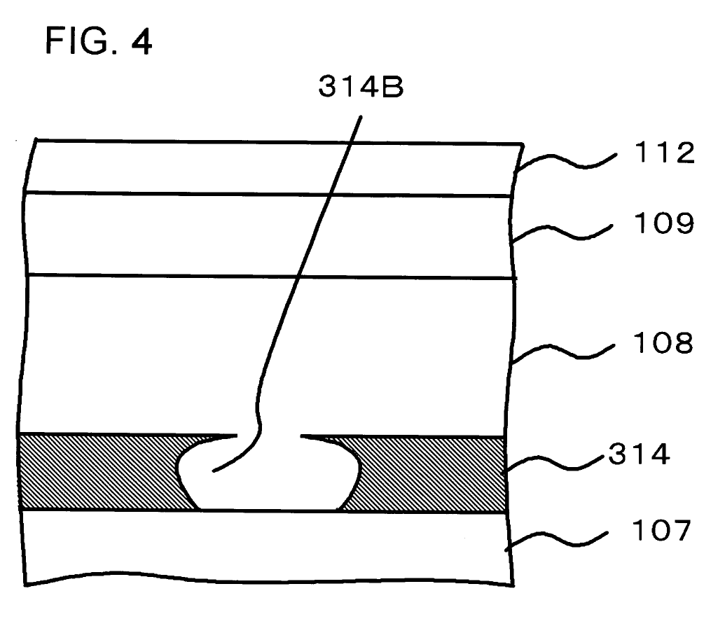

The above and other objects, advantages and features of the present invention will be more apparent from the following description of certain preferred embodiments taken in conjunction with the following drawings accompanying thereof.

[FIG. 1] It is a cross-sectional view, illustrating a group III nitride semiconductor device according to an embodiment of the present invention.

[FIG. 2] It is a diagram, illustrating a substantial part of the group III nitride semiconductor device.

[FIG. 3] It is a cross-sectional view, illustrating a group III nitride semiconductor device according to Example 2.

[FIG. 4] It is a cross-sectional view, illustrating a group III nitride semiconductor device according to a modified embodiment of the present invention.

[FIG. 5] It is a cross-sectional view, illustrating a conventional group III nitride semiconductor device.

[FIG. 6] It is a cross-sectional view, illustrating a conventional group III nitride semiconductor device.

[FIG. 7] It is a cross-sectional view, illustrating a substantial part of a group III nitride semiconductor device shown in FIG. 6.

### BEST MODE FOR CARRYING OUT THE INVENTION

A group III nitride semiconductor device of the present embodiment will be described as follows, in reference to FIG. 1. A group III nitride semiconductor device is a group III nitride semiconductor optical device, and is a laser diode 300.

First of all, an outline of such laser diode 300 will be described.

The laser diode 300 includes a first layer that is a group III nitride semiconductor (p-type GaN guide layer 107), a second layer, provided over the first layer and having an opening 314A formed therein (current confinement layer 314) and a third layer that is a group III nitride semiconductor, provided over the second layer and plugging the opening 314A formed in said second layer (p-type cladding layer 108).

An interface between the third layer and the first layer is located in a bottom of the opening 314A.

The second layer is a group III nitride semiconductor layer, and a width dimension of the opening 314A is minimized in the upper side of the opening 314A.

Next, a configuration of the laser diode 300 will be described in detail.

The laser diode 300 includes an n-type GaN substrate 101 serving as a semiconductor substrate, an Si-doped n-type GaN layer 102 provided on the n-type GaN substrate 101, an n-type cladding layer 103 provided on the Si-doped n-type GaN layer 102, an n-type optical confinement layer 104 provided on the n-type cladding layer 103, a three-period multiple-quantum wells (MQW) layer 105 serving as an active layer provided on the n-type optical confinement layer 104, a cap layer 106 provided on the three-period multiple-quantum wells (MQW) layer 105, a p-type GaN guide layer 107 provided on the cap layer 106, a current confinement layer 314 provided on the p-type GaN guide layer 107, a p-type cladding layer 108 provided on the current confinement layer 314 and a p-type contact layer 109 provided on the p-type cladding layer 108.

The Si-doped n-type GaN layer 102 is deposited on the side of the surface of the n-type GaN substrate 101, and an electrode 113 is provided in the side of the back surface of the n-type GaN substrate 101.

The Si-doped n-type GaN layer 102 has an Si concentration of, for example, 4×10¹⁷ cm⁻³, and a thickness thereof is 1 μm.

The n-type cladding layer 103 is composed of, for example, an Si-doped n-type Al_{0.05}Ga_{0.95}N, and exhibits, for example, an Si concentration of 4×10¹⁷ cm⁻³, and a thickness thereof of 2 μm. The n-type optical confinement layer 104 is, for example, composed of an Si-doped n-type GaN, and exhibits, for example, an Si concentration of 4×10¹⁷ cm⁻³, and a thickness thereof of 0.1 μm.

Further, the three-period multiple-quantum wells (MQW) layer 105 is configured of, for example, a well layer of In_{0.1}Ga_{0.9}N (for example 3 nm thick) and a barrier layer of undoped GaN (for example 10 nm thick).

The cap layer 106 is composed of magnesium (Mg) doped p-type Al_{0.2}Ga_{0.8}N.

The p-type GaN guide layer 107 is composed of magnesium (Mg) doped GaN, and for example, has an Mg concentration of 1×10¹⁹ cm⁻³ and a thickness of 0.1 μm.

The current confinement layer 314 is a group III nitride semiconductor layer, and composed of InₓGa_{y}Al_{1-x-y}N (0≦x≦1, 0≦y≦1 and x+y≦1). For example, the current confinement layer 314 is an AlN layer. In the present embodiment, the current confinement layer 314 is configured of a single layer.

A stripe-like opening 314A is formed in such current confinement layer 314.

In a cross section perpendicular to the elongating direction of the opening 314A, the width dimension of the opening 314A is minimized in the upper side of the opening 314A.

In the present embodiment, the width dimension of the opening 314A is monotonically decreased from the bottom side of the opening 314A toward the upper side of the opening 314A in the cross section perpendicular to the elongating direction of the opening 314A.

In other words, the geometry of the opening 314A is an inverse tapered shape, in which the width dimension thereof is decreased from the bottom side of the opening 314A toward the upper side of the opening 314A.

Further, an upper end portion of the side wall of the current confinement layer 314 forming the opening 314A more inwardly protrudes toward the inside of the opening 314A than any other sections of the side wall. More specifically, it can be understood that the upper end portion of the side wall of the current confinement layer 314 protrudes toward the inside of the opening 314A with a visor-like geometry.

Here, in the cross section perpendicular to the elongating direction of the opening 314A, the width dimension of the upper end portion of the opening 314A (minimum width of the opening 314A) is equal to or smaller than 2 μm.

The p-type cladding layer 108 is a layer composed of, for example, Mg-doped p-type Al_{0.05}Ga_{0.95}N (Mg concentration of 1×10¹⁹ cm⁻³ and thickness of 0.5 μm). Such p-type cladding layer 108 is provided over the current confinement layer 314 and plugs the opening 314A. An interface between the p-type cladding layer 108 and the p-type GaN guide layer 107 is present in the bottom of the opening 314A, and an interface between the p-type cladding layer 108 and the p-type GaN guide layer 107 is present on a plane substantially the same as a surface of the p-type GaN guide layer 107 in the side of the current confinement layer 314.

Further, an upper surface of the p-type cladding layer 108 (surface in the side of the p-type contact layer 109) is substantially flat.

The p-type contact layer 109 is a layer composed of a Mg-doped p-type GaN (for example, having an Mg concentration of equal to or lower than 2×10²⁰ cm⁻³ and thickness of 0.02 μm).

A p-electrode 112 is provided on such p-type contact layer 109.

Next, a method for manufacturing such laser diode 300 will be described.

First of all, the Si-doped n-type GaN layer 102, the n-type cladding layer 103, the n-type optical confinement layer 104, the three-period multiple-quantum wells (MQW) layer 105, the cap layer 106 and the p-type GaN guide layer 107 are deposited on the n-type GaN substrate 101 by, for example, an organometallic vapor phase deposition process (hereinafter referred to as MOVPE process).

Next, the current confinement layer 314 is deposited on the p-type GaN guide layer 107.

The current confinement layer 314 is formed by a process for converting the non-crystalline layer into the crystal layer, in which a non-crystalline layer is formed by a low temperature deposition and then the opening 314A is provided by an etching process and thereafter an upper layer is formed over the p-type cladding layer 108 at a temperature that is higher than a temperature for forming the non-crystalline layer.

AlN serving as the current confinement layer 314 is deposited (hereinafter referred to MOVPE process) at a low temperature of equal to or lower than 600 degree C. This is because a crack is generated in the AlN layer during the deposition process, when a monocrystalline AlN layer is manufactured on the p-type GaN guide layer 107 by a MOVPE process at a high-temperature. A non-crystalline AlN is deposited to have a thickness of about 0.1 μm at a lower temperature of equal to or lower than 600 degree C. Next, stripe-shaped opening 314A is formed by a selective etching employing a phosphoric acid-containing etchant solution. In such occasion, an etching process is conducted so that the width dimension of the upper end portion of the opening 314A is a minimum width dimension in the cross section perpendicular to the elongating direction of the opening 314A. This can be achieved by conducting the etching process at preferable conditions that can be achieved by precisely controlling a selection of an etchant solution and further a temperature for depositing AlN, a temperature of the etchant solution, an etching time or the like.

More specifically, a phosphoric acid-containing etchant solution having a low viscosity may be employed. For example, a phosphoric acid-containing etchant solution exhibiting a viscosity at 30 degree C. of equal to or lower than 15 cP (centipoises) (equal to or lower than 0.015 Pa·s may be employed, or, more preferably equal to or lower than 10 cP (0.01 Pa·s), and further preferably equal to or lower than 5 cP (0.005 Pa·s), may be employed.

Further, the temperature of the phosphoric acid-containing etchant solution may be preferably equal to or less than 60 degree C., and more preferably equal to or less than 50 degree C.

In addition to above, such phosphoric acid-containing etchant solution may be preferable to contain no strong acid except phosphoric acid.

Thereafter, the p-type cladding layer 108 is deposited on the current confinement layer 314 at a temperature higher than a deposition temperature for AlN layer, and further, the p-type contact layer 109 is deposited. In addition to above, the p-type cladding layer 108 is deposited so as to plug the opening 314A. Thereafter, the p-electrode 112 is provided.

Further, the n-electrode 113 is provided in the back surface of the n-type GaN substrate 101.

This allows obtaining the laser diode 300.

In such laser diode 300, the width dimension of the opening 314A in the current confinement layer 314 is minimized in the upper side of the opening 314A, and the upper portion of the side wall of the current confinement layer 314 constituting the opening 314A is configured to protrude toward the inside of the opening 314A.

Therefore, during the deposition of the p-type cladding layer 108, the source material constituting the p-type cladding layer 108 is difficult to be adhered on the side wall for forming the opening 314A, and crystal nuclei for the p-type cladding layer 108 is difficult to be formed on the side wall of the opening 314A.

This allows inhibiting a generation of a dislocation in vicinity of the opening 314A.

Since the present embodiment is configured that an upper portion of the side wall of the current confinement layer 314 constituting the opening 314A inwardly protruded toward the interior of the opening 314A, any dislocations extending from the upper portion of the side wall constituting such opening 314A toward the above thereof can be blocked. Therefore, as shown in FIG. 2, a dislocation 115 generated in vicinity of the opening 314A may be a loop-like dislocation. This allows inhibiting propagation toward the vicinity of the central portion inside of the opening 314A or a section in vicinity of the p-type cladding layer 108 in the side of the p-type contact layer 109. This allows reducing a decrease in the lifetime of the laser diode 300.

In addition to above, FIG. 2 shows an enlarged section surrounded by a dotted line of FIG. 1.

Further, since the dislocations are difficult to be generated in vicinity of the opening 314A, an increase in the thickness of the p-type cladding layer 108 in vicinity of the opening 314A that is larger than the design thickness can be prevented.

This allows preventing an increase in the operating voltage of the laser diode 300. Further, since an increase in the thickness in vicinity of the opening 314A in the p-type cladding layer 108 can be prevented, a difference in the actual optical confinement structure from the designed structure can be prevented, thereby reducing variations in the characteristics such as threshold current or kink level.

Further, in the present embodiment, the current confinement layer 314 is of a layer composed of InₓGa_{y}Al_{1-x-y}N (0≦x≦1, 0≦y≦1 and x+y≦1) , and more specifically of AlN layer.

An underlying layer in contact with the current confinement layer 314 is a p-type GaN guide layer 107, and an upper layer in contact with the current confinement layer 314 is a p-type cladding layer 108 composed of Mg-doped p-type Al_{0.05}Ga_{0.95}N. By selecting a group III nitride semiconductor layer for the current confinement layer 314 similarly as the layer immediately above the current confinement layer 314 and the layer immediately below the current confinement layer 314, a diffusion of the current confinement layer 314 as an impurity is prevented, and crystallization by a thermal processing can be relatively easily conducted.

Further, the AlN layer is employed as the current confinement layer 314 in the present embodiment. By selecting a binary compound for the current confinement layer 314, a flat surface is more easily obtained in the crystallization thereof, as compared with a multinary compound. Further, since AlN exhibits the largest band gap and the smallest refractive index in group III nitride semiconductors, the current confinement layer having a higher insulation performance and a sufficient optical confinement performance can be achieved.

Further, since the minimum width of the opening 314A is selected to be equal to or smaller than 2 μm, the opening 314A can be easily filled, and the p-type cladding layer 108 exhibiting less thickness variation and an improved flatness of the surface can be easily obtained.

It is intended that the present invention is not limited to the above-described embodiments, and various modifications thereof are available within the scope that can achieve the purpose of the present invention. For example, while the current confinement layer 314 is configured of a single layer in the above-described embodiment, the present invention is not limited thereto, and the current confinement layer 414 may be composed of a lower layer 416 formed on the p-type GaN guide layer 107 and an upper layer 417 formed on such lower layer 416, as shown in FIG. 3. For example, the lower layer 416 may be a layer composed of InₐGa_{b}Al_{1-a-b}N (0≦a<1, 0≦b<1, 0≦a+b<1), and the upper layer 417 may be a layer composed of In_{c}Ga_{d}Al_{1-c-d}N (0≦c≦1, 0≦d≦1, 0<c+d≦1).

Then, the Al content ratio of the upper layer 417 may be zero or smaller than the Al content ratio of the lower layer 416.

Since the concentration of atomic Al having higher reactivity is reduced in the upper layer 417 in such case, a layer of a modified material such as oxides is less likely to be formed in the surface of the upper layer 417.

Therefore, an improved adhesiveness between the current confinement layer 414 and a mask of a dielectric material such as SiO₂ is achieved, when the opening 414A is formed by a wet etching process in the current confinement layer 414.

This allows improving controllability for the width of the opening 414A.

Here, the upper layer 417 is preferably a layer composed of GaN.

When the upper layer 417 composed of GaN is formed, the adhesiveness with the above-described mask of the dielectric material is further improved, and in addition, a flat surface is easily to be obtained due to the binary compound, when it is crystallized, as compared with the multinary compound.

Further, the lower layer 416 is preferably an AlN layer.

In addition to above, the geometry of the opening 414A is the same as the geometry of the opening 314A in the above-described embodiment, and has the minimum width dimension in the upper side. Such minimum width dimension is preferably equal to or smaller than 2 μm.

Further, while the geometry of the opening 314A is an inverse tapered shape and is monotonically decreased from the bottom side of the opening toward the upper side thereof in the above-described embodiment, the geometry of the opening 314A is not limited thereto.

For example, as shown in FIG. 4, an opening 314B having a geometry, in which the width dimension is once increased from the bottom of the opening toward the upper side and the width dimension is minimized in the upper side of the opening, may be formed.

Since the geometry like the that of the opening 314B includes the upper end portion of the side wall of the current confinement layer 314 constituting the opening 314B that is configured to protrude toward the inside of the opening 314B, the source material constituting the p-type cladding layer 108 is less likely to be adhered on the side wall for forming the opening 314B when the p-type cladding layer 108 is deposited, and thus crystal nuclei for the p-type cladding layer 108 is less likely to be adhered on the side wall for forming the opening 314B.

Further, since the structure includes the upper end portion of the side wall of the current confinement layer 314 that protrudes toward the inside of the opening 314B, a dislocation extending toward the upper side is blocked by the upper portion of the side wall constituting such opening 314B. Therefore, a dislocation generated in vicinity of the opening 314B is a loop-like dislocation.

### EXAMPLES

Next, examples of the present invention will be described.

### Example 1

A group III nitride semiconductor device (laser diode) similar to that in the above-described embodiments was manufactured.

An n-type GaN (0001) substrate 101 having an n-type carrier density of about 1×10¹⁸ cm⁻³ was employed as the substrate.

A low-pressure MOVPE device at 300 hPa was employed in the manufacture of the device structure.

A gaseous mixture of hydrogen and nitrogen was employed as a carrier gas; trimethylgallium (TMG), trimethylaluminum (TMA) and trimethylindium (TMIn) were employed as Ga, Al and In sources, respectively; silane (SiH₄) was employed as an n-type dopant; and biscyclopentadienyl magnesium (Cp₂Mg) was employed as a p-type dopant.

In the beginning, respective depositions of an active layer, an n-type cladding layer, n-type and p-type cladding layers and a current confinement layer were conducted.

Hereinafter, the processes are called “active-layer-deposition process”. The n-type GaN substrate 101 was loaded into the low-pressure MOVPE device, and then the temperature of the n-type GaN substrate 101 was elevated while supplying ammonia (NH₃), and a deposition was started at a point in time reached to a deposition temperature. An Si-doped n-type GaN layer 102 (Si concentration: 4×10¹⁷ cm⁻³, thickness: 1 μm); an n-type cladding layer 103 composed of Si-doped n-type Al_{0.05}Ga_{0.95}N (Si concentration: 4×10¹⁷ cm⁻³, thickness: 2 μm); an n-type optical confinement layer 104 composed of Si-doped n-type GaN (Si concentration: 4×10¹⁷ cm⁻³, thickness: 0.1 μm); a three-period multiple-quantum wells (MQW) layer 105 composed of In_{0.1}Ga_{0.9}N well layer (thickness: 3 nm) and undoped GaN barrier layer (thickness: 10 nm); a cap layer 106 composed of Mg-doped p-type Al_{0.2}Ga_{0.8}N; and a p-type GaN guide layer 107 composed of a Mg-doped p-type GaN (Mg concentration: 2×10¹⁹ cm⁻³, thickness: 0.1 μm) were consecutively sequentially deposited.

A deposition of GaN was conducted at a substrate temperature of 1,080 degree C., at a TMG supply rate of 58 μmol/min., and at a NH₃ supply rate of 0.36 mol/min., and a deposition of AlGaN was conducted at a substrate temperature of 1,080 degree C., at a TMA supply rate of 36 μmol/min., at a TMG supply rate of 58 μmol/min., and at a NH₃ supply rate of 0.36 mol/min.

A deposition of the InGaN MQW was conducted at a substrate temperature of 850 degree C., at a TMG supply rate of 8 μmol/min., and at a NH₃ supply rate of 0.36 mol/min. In addition to above, a TMIn supply rate was 48 μmol/min. for the well layer.

After the depositions of these respective layers, the substrate temperature was reduced to around 400 degree C., a deposition of a non-crystalline AlN layer (which would be crystallized later to form a current confinement layer 314) was conducted. Supply rates of TMA and NH₃ were during the deposition of the non-crystalline AlN layer were 36 μmol/min. and 0.36 mol/min., respectively, and the thickness of the deposited film was 0.1 μm.

Next, a stripe-like opening 314A was formed in the non-crystalline AlN layer.

Hereinafter, such process is referred to as a “stripe-forming process”.

More specifically, SiO₂ was deposited to 100 nm on the non-crystalline AlN layer, and a resist was applied, and then a stripe pattern of 1.5 μm-wide was formed on the resist by a photolithographic process. Next, SiO₂ was etched through a mask of the resist with buffered hydrofluoric acid. Thereafter, the resist was eliminated with an organic solvent, and then a rinse with water was conducted.

The non-crystalline AlN layer was not etched or not damaged during the respective processes with buffered hydrofluoric acid, the organic solvent and water. Next, the non-crystalline AlN layer was etched through a mask of SiO₂.

A phosphoric acid-containing solution (contains no strong acid except phosphoric acid, viscosity: lower than 10 cP (0.01 Pa·s)) was employed as an etchant solution. Regions of the non-crystalline AlN layer that were not covered with the SiO₂ mask were removed by the etching process for 8.5 minutes within the etchant solution retained at around 50 degree C.

This provides the minimum width dimension of the opening 314A in the upper side of the opening in the cross section perpendicular to the elongating direction of the opening 314A.

Further, the geometry of the opening 314A was an inverse tapered shape, in which the width dimension thereof is decreased from the bottom side of the opening 314A toward the upper side of the opening 314A.

Here, in order to provide a minimum width dimension of the opening 314A in the upper side of the opening, it is critical that an etchant solution is suitably selected, a temperature of the etchant solution and an etching time are precisely controlled, and the etching process is conducted at preferable conditions.

In addition to above, SiO₂ was employed as the mask for etching the non-crystalline AlN layer in this case, SiNₓ or an organic compound including a resist may alternatively be employed, provided that the material is not affected by an etchant solution.

Thereafter, SiO₂ employed as the mask was further removed with buffered hydrofluoric acid. A p-type cladding layer 108 was deposited so as to fill thus formed opening 314A. Hereinafter, such process is referred to as “p-cladding regrowth process”.

A sample having the opening 314A formed therein was loaded into the MOVPE reactor, and then a temperature was elevated to 1,100 degree C. that is equivalent to a deposition temperature under the NH₃ supply rate of 0.36 mol/min. After reaching 1,100 degree C., the p-type cladding layer 108 composed of Mg-doped p-type Al_{0.05}Ga_{0.95}N (Mg concentration: 1×10¹⁹ cm⁻³, thickness: 0.5 μm) was deposited, and the substrate temperature was decreased to 1,080 degree C., and then a p-type contact layer 109 composed of a Mg-doped p-type GaN (Mg concentration: 1×10²⁰ cm⁻³, thickness: 0.02 μm) was deposited. The conditions for deposing AlGaN and GaN were similar as that for active-layer growth process that was described ahead except for a difference of a do·nt.

An observation with a scanning electron microscope was conducted after the p-cladding regrowth process, and no defects such as cracks or pits were found on the surface and the AlN layer (current confinement layer 314) was crystallized, and it was confirmed that the flat filling was achieved with the p-type cladding layer 108.

However, the region regrown on such crystallized AlN layer (current confinement layer 314) was observed in detail, and somewhat waved morphology was observed.

The vicinity of the opening 314A of the sample was observed by a cross-sectional transmission electron microscope, and it was found that dislocations existed at higher density of 5×10¹⁰ to 1×10¹² cm⁻² in the crystallized AlN layer (current confinement layer 314).

Further, it was also found that a threading dislocation having a similar density and propagating in a direction perpendicular to the substrate was also present in the p-type cladding layer 108 on the crystallized AlN layer (current confinement layer 314).

It was further found that the threading dislocation was generated from the crystallized AlN layer (current confinement layer 314) and did not propagate below the crystallized AlN layer (current confinement layer 314), and it was also found that the dislocations generated in the side wall of the opening 314A of the crystallized AlN (current confinement layer 314) were all loop-like and were terminated in vicinity of the side wall, and that no propagation of a dislocation from the side wall toward the inside center section of the opening 314A or toward the upward of the current confinement layer 314 was observed.

Further, it was found that no dislocation introduced from a regrowth interface was observed in the p-type cladding layer 108 on opening 314A, and the upper surface of the p-type cladding layer 108 was extremely flat.

A p-electrode 112 and an n-electrode 113 were formed by a vacuum deposition process over the structural member having the n-type GaN substrate 101, the Si-doped n-type GaN layer 102, the n-type cladding layer 103, the n-type optical confinement layer 104, the three-period multiple-quantum wells (MQW) layer 105, the cap layer 106, the p-type GaN guide layer 107, the current confinement layer 314, the p-type cladding layer 108 and the p-type contact layer 109, which were obtained as described above. Such process is referred to as “electrode-forming process”.

The sample after the electrode-forming process was cleaved in the direction perpendicular to the longitudinal direction of the opening 314A to obtain the semiconductor device 300. The device length was selected to be 500 μm.

The above-described semiconductor device 300 was fused to a heat sink to investigate a luminescence property, and the results was that a laser oscillation was observed at a current density of 2.8 kA/cm² and a voltage of 4.1 V on an average. Further, an average lifetime under 120 mW-output was equal to or higher than 10,000 hours.

### Example 2

In the present example, a laser diode 400 shown in FIG. 3 was manufactured.

This laser diode 400 is different from the laser diode 300 of Example 1, in terms of having a current confinement layer 414 of a dual layer structure.

The other aspects thereof are similar to the laser diode 300 of Example 1.

First of all, similarly as in Example 1, the Si-doped n-type GaN layer 102, the n-type cladding layer 103, the n-type optical confinement layer 104, the three-period multiple-quantum wells (MQW) layer 105, the cap layer 106 and the p-type GaN guide layer 107 were deposited on the n-type GaN substrate 101.

Next, a non-crystalline AlN (would be crystallized later to serve an underlying layer 416 of the current confinement layer 414) was deposited on the p-type GaN guide layer 107.

The depositing condition of the non-crystalline AlN layer was the same as in Example 1.

Further, subsequently, a non-crystalline GaN (would be crystallized later to serve an upper layer 417 of the current confinement layer 414) was deposited at a deposition temperature that is the same as that for the non-crystalline AlN.

Supply rates of TMG and NH₃ during depositing the non-crystalline GaN were 12 μmol/min. and 0.36 mol/min., respectively, and the deposition film thickness was 0.01 μm.

Next, a stripe-like opening 414A was formed in the non-crystalline AlN layer and the non-crystalline GaN layer by a “stripe-forming process” similarly as in Example 1.

SiO₂ was deposited to 100 nm on the non-crystalline GaN layer, and a resist was applied, and then a stripe pattern of 1.5 μm-wide was formed on the resist by a photolithographic process.

Next, SiO₂ was etched through a mask of the resist with buffered hydrofluoric acid, and then, the resist was eliminated with an organic solvent, and then a rinse with water was conducted.

Either of the non-crystalline GaN and the non-crystalline AlN were not etched or not damaged during the respective processes with buffered hydrofluoric acid, the organic solvent and water.

Next, the non-crystalline GaN and the non-crystalline AlN were etched through a mask of SiO₂. A solution containing phosphoric acid and sulfuric acid mixed at a volumetric ratio of 1:1 was employed as an etchant solution. Regions of the non-crystalline GaN layer the non-crystalline AlN layer that were not covered with the SiO₂ mask were removed by the etching process for 8.5 minutes within the aforementioned etchant solution retained at around 90 degree C.

Thereafter, SiO₂ employed as the mask was further removed with buffered hydrofluoric acid.

The width dimension of the opening 414A was minimized in the upper side of the opening 414A in the cross section perpendicular to the elongating direction of the opening 414A.

Further, the geometry of the opening 414A was an inverse tapered shape, in which the width dimension thereof is monotonically decreased from the bottom side of the opening 414A toward the upper side of the opening 414A.

The minimum width dimension of the opening 414A was 1.5 μm.

In the present example, the opening 414A was formed to have a geometry, in which the width dimension was minimum in the upper side of the opening 414A, even if the etching time, the etchant solution temperature and the etching time during the formation of the opening 414A were changed. The opening 414A having a desired geometry was able to be formed under wider process conditions, as compared with the case of Example 1.

This is because the surface of the non-crystalline GaN is less likely to have a modified layer such as an oxide formed thereon, as compared with the non-crystalline AlN, and thus provides better adherence with the etch mask of SiO₂.

It is considered that this allows that the non-crystalline AlN and the non-crystalline GaN are less likely to be side-etched when the opening 414A is formed by an etch process, and thus the opening 414A having a geometry, in which the width dimension was minimum in the upper side of the opening 414A can be obtained.

Thereafter, a “p-cladding regrowth process” was conducted similarly as in Example 1, and further, a p-type contact layer 109 was deposited similarly as in Example 1.

An observation with a scanning electron microscope was conducted after the p-cladding regrowth process, and, similarly as in Example 1, no defects such as cracks or pits were found on the surface and both of the AlN layer (underlying layer 416) and the GaN layer (upper layer 417) were crystallized, and it was confirmed that the flat filling was achieved.

Further, the region regrown on the upper layer 417 was observed in detail, and, similarly as in Example 1, somewhat waved morphology was observed.

Further, the vicinity of the opening 414A was observed by a cross-sectional transmission electron microscope, and the results shows that the density of the dislocation and the configuration of the dislocation were substantially the same as in Example 1, and it was also found that dislocations existed at higher density of 5×10¹⁰ to 1×10¹² cm⁻² in the current confinement layer 414.

Further, it was also found that a threading dislocation having a similar density as that of the current confinement layer 414 and propagating in a direction perpendicular to the substrate was also present in the p-type cladding layer 108 on the current confinement layer 414.

It was further found that the threading dislocation generated from the current confinement layer 414 did not propagate below the current confinement layer 414.

It was also found that the dislocations generated in the side wall of the opening 414A of the current confinement layer 414 were all loop-like and were terminated in vicinity of the side wall, and that no propagation of a dislocation from the side wall toward the inside center section of the opening 414A or toward the upward of the current confinement layer 414 was observed.

Further, it was found that no dislocation introduced from a regrowth interface was observed in the p-type cladding layer 108 on the opening 414A, and the upper surface of the p-type cladding layer 108 was extremely flat.

Next, an “electrode-forming process” was conducted similarly as in Example 1, and the sample after the electrode-forming process was cleaved in the direction perpendicular to the longitudinal direction of the opening 414A to obtain the semiconductor device 400. The device length was selected to be 500 μm.

Concerning the characteristics of such semiconductor device 400, the threshold current density, the operating voltage and the angle of beam emission were all equivalent to that obtained in Example 1, and variations in the characteristics of the whole semiconductor device 400 were further reduced to about a half thereof, as compared in the case of Example 1.

It is considered that this is because a process tolerance in the “stripe-forming process” was improved by an introduction of the GaN layer (upper layer 417), and distributions of variations of the regrowth thickness of the p-type cladding layer 108 or the width of the opening 414A in the wafer surface in the opening 414A were improved.

### Comparative Example

A laser diode 200 having a conventional structure shown in FIG. 6 was manufactured.

The structure thereof was similar to that in Example 1, except that the geometry of the opening 114A was a forward tapered geometry.

In the manufacturing process of the laser diode 200, when the current confinement layer 114 was formed, a non-crystalline AlN layer is formed, and a wet etching was conducted at 80 degree C. with an etchant solution containing phosphoric acid and sulfuric acid (volumetric ratio: 1:1; viscosity at 30 degree C.: about 24 cP (0.024 Pa·s)) to form the opening 114A. Other aspects were similar to Example 1.

In such laser diode 200, a larger number of dislocations were generated in a side wall for forming the opening 114A of the current confinement layer 114, and the dislocations were propagated and extended into the central section inside of the opening 114A and toward the upside of the upper surface of the current confinement layer 114.

Further, a section located above the opening 114A in the upper surface of the p-type cladding layer 108 on the current confinement layer 114 was raised, and thus the upper surface of the p-type cladding layer 108 was not flat.

Such laser diode 200 exhibited larger variations in the device characteristic, and the average threshold current density was 3.5 KA/cm², an average threshold voltage was 4.9 V, and an average lifetime under 120 mW-output was about 2,000 hours.

In the laser diode 200 of Comparative Example, variations in the device characteristic was twice or larger and the reliability was considerably lower, as compared with the laser diodes of Examples 1 and 2.

1. A group III nitride semiconductor device, comprising:
a first layer containing a group III nitride semiconductor;
a second layer, provided over said first layer and having an opening formed therein; and
a third layer containing a group III nitride semiconductor, provided over said second layer and plugging said opening formed in said second layer,
wherein an interface between said third layer and said first layer is located in a bottom of said opening, and
wherein a width dimension of said opening in said second layer is minimized in the upper side of said opening.

2. The group III nitride semiconductor device as set forth in claim 1,
wherein said opening is inverse-tapered, in which the width dimension is reduced from the bottom side of the opening toward the upper side of the opening.

3. The group III nitride semiconductor device as set forth in claim 1,
wherein said second layer is a layer that contains
InₓGa_{y}Al_{1-x-y}N
(where 0≦x≦1, 0≦y≦1 and x+y≦1).

4. The group III nitride semiconductor device as set forth in claim 3, wherein said second layer is layer a containing aluminum nitride (AlN).

5. The group III nitride semiconductor device as set forth in claim 1,
wherein said second layer includes a lower layer formed over said first layer and an upper layer formed over the lower layer,
wherein said lower layer is a layer composed of
InₐGabAl_{1-a-b}N (where 0≦a<1 ,0≦b<1 and 0≦a+b<1), wherein said upper layer is a layer composed of
In_{c}Ga_{d}Al_{1-c-d}N
(where 0≦c≦1, 0≦d≦1 and 0<c+d≦1), and
wherein a content ratio of aluminum (Al) in said upper layer is zero or smaller than a content ratio of Al in said lower layer.

6. The group III nitride semiconductor device as set forth in claim 5, wherein said upper layer is a layer composed of gallium nitride (GaN).

7. The group III nitride semiconductor device as set forth in claim 1,
wherein a minimum width of said opening is equal to or smaller than 2 μm.

8. The group III nitride semiconductor device as set forth in claim 1,
wherein said group III nitride semiconductor device is a laser diode, and
said second layer is a current confinement layer.

9. A method for manufacturing a group III nitride semiconductor device, comprising:
providing a second layer on a first layer, said first layer being a group III nitride semiconductor layer;
forming an opening in said second layer; and
plugging said opening of said second layer and providing a third layer, said third layer being provided on said second layer and being a group III nitride semiconductor layer,
wherein said forming the opening in the second layer includes forming said opening so as to provide a minimum width dimension in the upper side of said opening.
